(19) United States
(12) Patent Application Publication
(10) Pub. No.: US 2023/0059737 A1
(43) Pub. Date: Feb. 23, 2023

(54) SILICON CARBIDE EPITAXIAL SUBSTRATE AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventors: Hironori ITOH, Osaka (JP); Taro NISHIGUCHI, Osaka (JP); Takashi SAKURADA, Osaka (JP)

(21) Appl. No.: 17/793,399

(22) PCT Filed: Jan. 19, 2021
(86) PCT No.: PCT/JP2021/001693

§ 371 Date: Jul. 17, 2022

(30) Foreign Application Priority Data
Jan. 29, 2020 (JP) 2020-012522

(51) Int. Cl. C30B 29/36; H01L 21/02; H01L 29/16; H01L 29/78; H01L 29/66

(52) U.S. Cl. CPC C30B 29/36; H01L 21/02378; H01L 21/02529; H01L 21/0262; H01L 21/02658; H01L 29/1608; H01L 29/7802; H01L 29/66068; C30B 25/20

(57) ABSTRACT

A silicon carbide epitaxial substrate according to a present disclosure includes a silicon carbide substrate and a silicon carbide epitaxial layer disposed on the silicon carbide substrate. The silicon carbide epitaxial layer includes a boundary surface in contact with the silicon carbide substrate and a main surface opposite to the boundary surface. The main surface has an outer circumferential edge, an outer circumferential region extending within 5 mm from the outer circumferential edge, and a central region surrounded by the outer circumferential region. When an area density of double Shockley stacking faults in the outer circumferential region is defined as a first area density, and an area density of double Shockley stacking faults in the central region is defined as a second area density, the first area density is five or more times as large as the second area density, the second area density is 0.2 cm⁻² or more.

### TECHNICAL FIELD

The present disclosure relates to a silicon carbide epitaxial substrate and a method of manufacturing silicon carbide semiconductor device. This application claims priority based on Japanese Patent Application No. 2020/012522 filed on Jan. 29, 2020. The entire contents of the Japanese Patent Application are incorporated herein by reference.

### BACKGROUND ART

Japanese Unexamined Patent Application Publication No. 2018-162178 (Patent Document 1) discloses an epitaxial growth method of silicon carbide characterized in that a double Shockley stacking fault is 5 cm⁻² or less.

### CITATION LIST

### Patent Literature

Patent Document 1: Japanese Unexamined Patent Application Publication No. 2018-162178

### SUMMARY OF INVENTION

A silicon carbide epitaxial substrate according to a present disclosure includes a silicon carbide substrate and a silicon carbide epitaxial layer disposed on the silicon carbide substrate. The silicon carbide epitaxial layer includes a boundary surface in contact with the silicon carbide substrate and a main surface opposite to the boundary surface, the main surface has an outer circumferential edge, an outer circumferential region extending within 5 mm from the outer circumferential edge, and a central region surrounded by the outer circumferential region. When an area density of double Shockley stacking faults in the outer circumferential region is defined as a first area density and an area density of double Shockley stacking faults in the central region is defined as a second area density, the first area density is five or more times as large as the second area density. The second area density is 0.2 cm⁻² or more. An area density of single Shockley stacking faults in the outer circumferential region is 0.5 cm⁻² or less.

### BRIEF DESCRIPTION OF DRAWINGS

FIG. 1 is a schematic plan view showing a configuration of a silicon carbide epitaxial substrate according to the present embodiment.

FIG. 2 is a schematic cross-sectional view taken along line II-II of FIG. 1.

FIG. 3 is an enlarged schematic plan view showing a state in which an outer circumferential region is measured by a photoluminescence method.

FIG. 4 is an enlarged schematic plan view showing a state in which the central region is measured by the photoluminescence method.

FIG. 5 is a schematic plan view showing a state in which the first main surface is observed.

FIG. 6 is a schematic diagram showing the shape of the first main surface when the bow has a negative value.

FIG. 7 is a schematic diagram showing the shape of the first main surface when the bow has a positive value.

FIG. 8 is a flowchart showing an outline of a method of manufacturing a silicon carbide epitaxial substrate according to the present embodiment.

FIG. 9 is a schematic cross-sectional view showing a first step of the method of manufacturing a silicon carbide epitaxial substrate according to the present embodiment.

FIG. 10 is a schematic cross-sectional view showing an ion implantation process of the method of manufacturing a silicon carbide epitaxial substrate according to the present embodiment.

FIG. 11 is a schematic cross-sectional view showing a hydrogen treatment step of the method of manufacturing a silicon carbide epitaxial substrate according to the present embodiment.

FIG. 12 is a flowchart showing an outline of a method of manufacturing a silicon carbide semiconductor device according to the present embodiment.

FIG. 13 is a schematic cross-sectional view showing an ion implantation process in the method of manufacturing a silicon carbide semiconductor device according to the present embodiment.

FIG. 14 is a schematic cross-sectional view showing an oxide film forming step of the method of manufacturing a silicon carbide semiconductor device according to the present embodiment.

FIG. 15 is a schematic cross-sectional view showing the configuration of the silicon carbide semiconductor device according to the present embodiment.

FIG. 16 is a diagram showing a change in bow before and after epitaxial growth.

### DETAILED DESCRIPTION

### Problems to be Solved by the Present Disclosure

An object of the present disclosure is to provide a silicon carbide semiconductor device capable of improving reliability and a method of manufacturing a silicon carbide epitaxial substrate.

### [Advantageous Effect of the Present Disclosure]

According to the present disclosure, it is possible to provide a silicon carbide semiconductor device capable of improving reliability and a method of manufacturing a silicon carbide epitaxial substrate.

### DESCRIPTION OF EMBODIMENTS

First, an outline of an embodiment of the present disclosure will be described. Regarding crystallographic indications in the present specification, an individual orientation is represented by [ ], a group orientation is represented by < >, an individual plane is represented by ( ), and a group plane is represented by { }. Generally, a negative index is supposed to be crystallographically indicated by putting “−” (bar) above a numeral but is indicated by putting the negative sign before the numeral in the present specification.

(1) Silicon carbide epitaxial substrate 100 according to the present disclosure includes a silicon carbide substrate 10 and a silicon carbide epitaxial layer 20 disposed on silicon carbide substrate 10. Silicon carbide epitaxial layer 20 includes a boundary surface 11 in contact with silicon carbide substrate 10 and a main surface 1 opposite to boundary surface 11. Main surface 1 has an outer circumferential edge 5, an outer circumferential region 31 extending within 5 mm from outer circumferential edge 5, and a central region 32 surrounded by outer circumferential region 31. When an area density of double Shockley stacking faults 7 in outer circumferential region 31 is defined as a first area density and an area density of double Shockley stacking faults 7 in central region 32 is defined as a second area density, the first area density is five or more times as large as the second area density. The second area density is 0.2 cm⁻² or more. An area density of single Shockley stacking faults 8 in outer circumferential region 31 is 0.5 cm⁻² or less.

(2) In silicon carbide epitaxial substrate 100 according to (1) above, a bow quantitatively defining an amount of warpage of main surface 1 may be a negative value.

(3) In silicon carbide epitaxial substrate 100 according to (1) or (2), the second area density is 1.0 cm⁻² or less

(4) In silicon carbide epitaxial substrate 100 according to any one of (1) to (3) above, the first area density is 2.0 cm⁻² or more.

(5) A method of manufacturing a silicon carbide semiconductor device 300 includes: preparing silicon carbide epitaxial substrate 100 according to any one of (1) to (4); and processing silicon carbide epitaxial substrate 100.

### DETAILS OF EMBODIMENT OF THE PRESENT DISCLOSURE

Hereinafter, embodiments of the present disclosure will be described in detail. In the following description, the same or corresponding elements are denoted by the same reference numerals, and the same description thereof will not be repeated.

(Silicon Carbide Epitaxial Substrate)

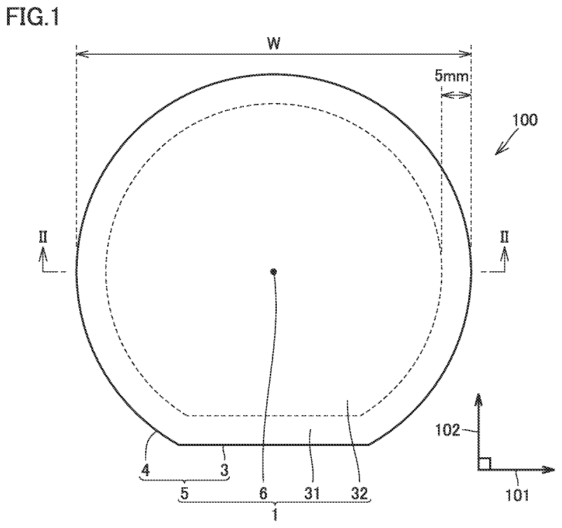

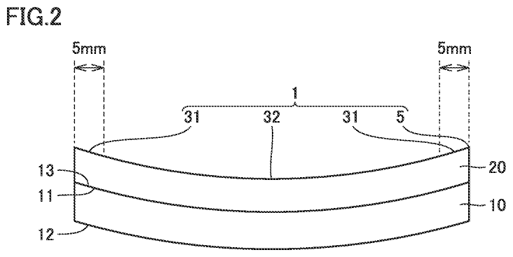

FIG. 1 is a schematic plan view showing the configuration of a silicon carbide epitaxial substrate according to the present embodiment. FIG. 2 is a schematic cross-sectional view taken along line II-II of FIG. 1. As shown in FIGS. 1 and 2, a silicon carbide epitaxial substrate 100 according to the present embodiment includes a silicon carbide substrate 10 and a silicon carbide epitaxial layer 20. Silicon carbide epitaxial layer 20 is disposed on a silicon carbide substrate 10. Silicon carbide epitaxial layer 20 is in contact with silicon carbide substrate 10. Silicon carbide epitaxial layer 20 has a main surface (a first main surface 1) of silicon carbide epitaxial substrate 100. Silicon carbide substrate 10 has a backside surface (a second main surface 12) of silicon carbide epitaxial substrate 100.

Silicon carbide epitaxial layer 20 has the main surface (first main surface 1) and a boundary surface 11. Boundary surface 11 is opposite to first main surface 1. Boundary surface 11 is in contact with silicon carbide substrate 10. First main surface 1 includes an outer circumferential edge 5, an outer circumferential region 31, and a central region 32. Outer circumferential region 31 is a region within 5 mm from outer circumferential edge 5. As shown in FIG. 1, when viewed in the thickness direction of silicon carbide epitaxial layer 20, outer circumferential region 31 is annular. Central region 32 is surrounded by outer circumferential region 31. Central region 32 includes a center 6 of first main surface 1. In the present specification, the thickness direction of silicon carbide epitaxial layer 20 is a direction perpendicular to a flat surface when silicon carbide epitaxial substrate 100 is disposed on the flat surface such that the backside surface (second main surface 12) of silicon carbide epitaxial substrate 100 is in contact with the flat surface.

Outer circumferential edge 5 has, for example, an orientation flat 3 and an arc-shaped portion 4. Orientation flat 3 extends along a first direction 101. As shown in FIG. 1, orientation flat 3 is linear when viewed in the thickness direction of silicon carbide epitaxial layer 20. Arc-shaped portion 4 is continuous with orientation flat 3. Arc-shaped portion 4 has an arc shape when viewed in the thickness direction of silicon carbide epitaxial layer 20. Center 6 of first main surface 1 is positioned at the center of a circle including arc-shaped portion 4 when viewed in the thickness direction of silicon carbide epitaxial layer 20.

As shown in FIG. 1, when viewed in the thickness direction of silicon carbide epitaxial layer 20, first main surface 1 extends along each of first direction 101 and a second direction 102. When viewed in the thickness direction of silicon carbide epitaxial layer 20, first direction 101 is a direction perpendicular to second direction 102.

First direction 101 is, for example, a <11-20> direction. First direction 101 may be, for example, a [11-20] direction. First direction 101 may be a direction obtained by projecting the <11-20> direction onto first main surface 1. In other words, first direction 101 may be, for example, a direction including the <11-20> direction component.

Second direction 102 is, for example, a <1-100> direction. Second direction 102 may be, for example, a [1-100] direction. Second direction 102 may be, for example, a direction obtained by projecting the <1-100> direction onto first main surface 1. In other words, second direction 102 may be, for example, a direction including the <1-100> direction component.

First main surface 1 may be a surface inclined with respect to a {0001} plane. When first main surface 1 is inclined with respect to the {0001} plane, an inclination angle (off angle) with respect to the {0001} plane is, for example, from 2° to 6°. When first main surface 1 is inclined with respect to the {0001} plane, an inclination direction (off direction) of first main surface 1 is, for example, the <11-20> direction.

As shown in FIG. 1, a maximum diameter W (diameter) of first main surface 1 is not particularly limited. Maximum diameter W is 4 inches, for example. Maximum diameter W may be 4 inches or more, or 6 inches or more. The upper limit of maximum diameter W is not particularly limited. Maximum diameter W may be, for example, 8 inches or less.

In the present specification, 2 inches means 50 mm or 50.8 mm (25.4 mm/inch×2 inches). 3 inches means 75 mm or 76.2 mm (25.4 mm/inch×3 inch). 4 inches means 100 mm or 101.6 mm (25.4 mm/inch×4 inches). 5 inches means 125 mm or 127.0 mm (25.4 mm/inch×5 inches). 6 inches means 150 mm or 152.4 mm (25.4 mm/inch×6 inches). 8 inches means 200 mm or 203.2 mm (25.4 mm/inch×8 inches).

As shown in FIG. 2, silicon carbide substrate 10 has second main surface 12 and a third main surface 13. Third main surface 13 is opposite to second main surface 12. Second main surface 12 is a backside surface of silicon carbide epitaxial substrate 100. Second main surface 12 is spaced apart from silicon carbide epitaxial layer 20. Third main surface 13 is in contact with silicon carbide epitaxial layer 20. The polytype of silicon carbide constituting silicon carbide substrate 10 is, for example, 4H. Similarly, the polytype of silicon carbide constituting silicon carbide epitaxial layer 20 is, for example, 4H.

Silicon carbide substrate 10 contains an n-type impurity such as nitrogen (N). The conductivity type of silicon carbide substrate 10 is, for example, n-type. The thickness of silicon carbide substrate 10 is, for example, from 350 m to 500 m. Silicon carbide epitaxial layer 20 contains an n-type impurity such as nitrogen. The conductivity type of silicon carbide epitaxial layer 20 is, for example, n-type. A concentration of the n-type impurities included in silicon carbide epitaxial layer 20 may be lower than a concentration of the n-type impurities included in silicon carbide substrate 10.

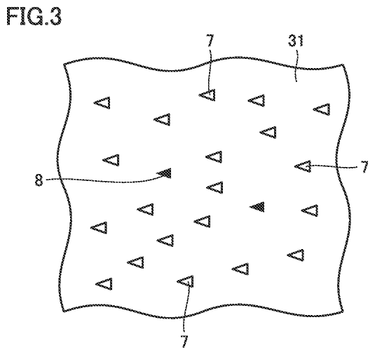

FIG. 3 is an enlarged schematic plan view showing a state in which outer circumferential region 31 is measured by a photoluminescence method. As shown in FIG. 3, a double Shockley stacking fault 7 exists in outer circumferential region 31 of silicon carbide epitaxial layer 20. The area density of double Shockley stacking fault 7 in outer circumferential region 31 is a first area density. The first area density may be, for example, 2.0 cm⁻² or more, or 4.0 cm⁻² or more. The first area density is a value obtained by dividing the total number of double Shockley stacking faults 7 existing in outer circumferential region 31 by the area of outer circumferential region 31.

As shown in FIG. 3, there may or may not be a single Shockley stacking fault 8 in outer circumferential region 31 of silicon carbide epitaxial layer 20. The area density (a third area density) of single Shockley stacking fault 8 in outer circumferential region 31 is, for example, 0.5 cm⁻² or less. The third area density is a value obtained by dividing the total number of single Shockley stacking faults 8 existing in outer circumferential region 31 by the area of outer circumferential region 31.

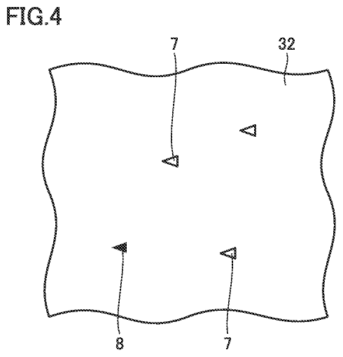

FIG. 4 is an enlarged schematic plan view showing a state in which central region 32 is measured by the photoluminescence method. As shown in FIG. 4, double Shockley stacking fault 7 exists in central region 32 of silicon carbide epitaxial layer 20. The area density of double Shockley stacking fault 7 in central region 32 is a second area density. The second area density is 0.2 cm⁻² or more. The second area density may be 0.4 cm⁻² or more or may be 0.6 cm⁻² or more. The second area density may be, for example, 1.0 cm⁻² or less, or 0.8 cm⁻² or less. The second area density is a value obtained by dividing the total number of double Shockley stacking faults 7 existing in central region 32 by the area of central region 32.

The first area density is five times or more as large as the second area density. The first area density may be seven times or more as large as the second area density, or may be ten times or more as large as the second area density. There may or may not be single Shockley stacking fault 8 in central region 32 of silicon carbide epitaxial layer 20. The area density (a fourth area density) of single Shockley stacking fault 8 in central region 32 is 0.5 cm⁻² or less. The fourth area density may be, for example, 0.3 cm⁻² or less, or may be 0.1 cm-2 or less. Preferably, there is no single Shockley stacking fault 8 in central region 32. The fourth area density is a value obtained by dividing the total number of single Shockley stacking faults 8 existing in central region 32 by the area of central region 32.

(Method of Measuring Area Density of Stacking Fault)

Next, a method of measuring the area density of each of single Shockley stacking fault 8 and double Shockley stacking fault 7 will be described.

For observation of each of single Shockley stacking fault 8 and double Shockley stacking fault 7, for example, a photoluminescence imaging device (model number: PLI-200) manufactured by Photon Design, Inc. is used. When a measurement region of silicon carbide epitaxial substrate 100 is irradiated with excitation light, photoluminescence light is observed from the measurement region. As the excitation light source, for example, a mercury xenon lamp is used. The excitation light from the light source passes through a bandpass filter (313 nm) on the irradiation side and is then irradiated onto the measurement region. Thus, photoluminescence light is emitted from the measurement region.

Photoluminescence light reaches a light-receiving element such as a camera after passing through a bandpass filter on the light-receiving side. As described above, the photoluminescence image of the measurement region is captured.

The emission wavelengths of single Shockley stacking fault 8 are near 420 nm. On the other hand, the emission wavelengths of double Shockley stacking fault 7 are near 510 nm. Therefore, each stacking fault can be identified by changing the wavelength of the bandpass filter on the light-receiving side. To be more specific, single Shockley stacking fault 8 can be observed by setting the wavelengths of the bandpass filter on the light-receiving side to 420 nm. Double Shockley stacking fault 7 can be observed by setting the wavelength of the bandpass filter on the light-receiving side to 510 nm. In the observed photoluminescence image, each of single Shockley stacking fault 8 and double Shockley stacking fault 7 emits light darker than the surrounding region.

While moving silicon carbide epitaxial substrate 100 in a direction parallel to first main surface 1 of silicon carbide epitaxial layer 20, a photoluminescence image of the entire first main surface 1 is captured. The size of one field of view of the photoluminescence image is, for example, 2.6 mm×2.6 mm. First main surface 1 is composed of outer circumferential region 31 and central region 32. In the acquired photoluminescence image, the number of each of single Shockley stacking fault 8 and double Shockley stacking fault 7 is specified.

(Amount of Warpage)

Next, a method for measuring the amount of warpage of first main surface 1 of silicon carbide epitaxial substrate 100 will be described. The amount of warpage of first main surface 1 can be measured by, for example, Flatmaster manufactured by Tropel, Inc. First, silicon carbide epitaxial substrate 100 is disposed on a flat surface. In a state where second main surface 12 is disposed on a flat surface, first main surface 1 opposite to second main surface 12 is observed.

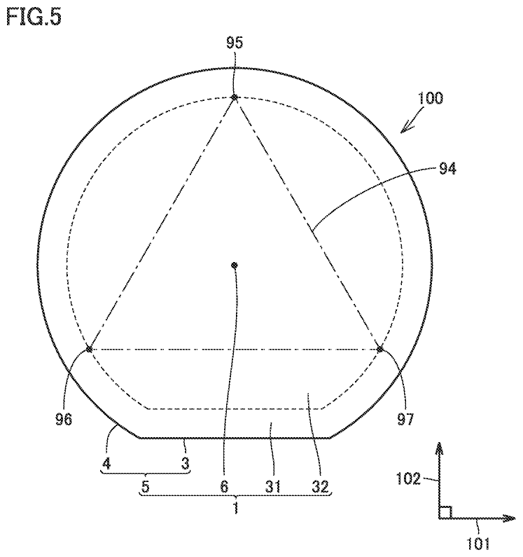

FIG. 5 is a schematic plan view showing a state in which first main surface 1 is observed. As shown in FIG. 5, a three point reference plane 94 of first main surface 1 is determined. Three point reference plane 94 is a virtual plane including three points (a fifth position 95, a sixth position 96, and a seventh position 97) on the boundary line between central region 32 and outer circumferential region 31. A triangle formed by connecting fifth position 95, sixth position 96, and seventh position 97 is an equilateral triangle. As shown in FIG. 5, when viewed in the thickness direction of silicon carbide epitaxial substrate 100, the center of first main surface 1 coincides with the center of the equilateral triangle.

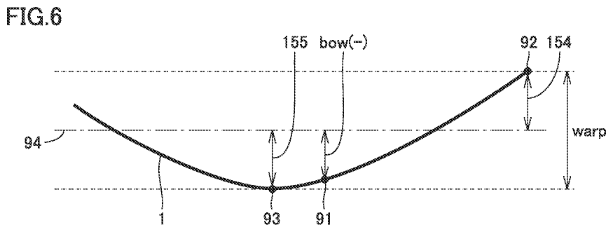

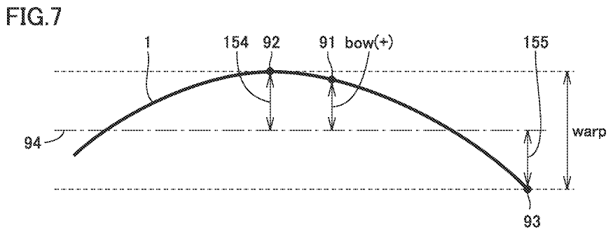

As indices for quantifying the amount of warpage, there are a bow and a warp. FIG. 6 is a schematic diagram showing the shape of first main surface 1 when the bow has a negative value. FIG. 7 is a schematic diagram showing the shape of first main surface 1 when the bow has a positive value. As shown in FIGS. 6 and 7, in the direction perpendicular to three point reference plane 94, the sum of a distance (a first distance 154) between a highest position 92 of first main surface 1 viewed from three point reference plane 94 and a distance (a second distance 155) between a lowest position 93 of first main surface 1 viewed from three point reference plane 94 and three point reference plane 94 is the warp. In a direction perpendicular to three point reference plane 94, a distance between a position 91 of center 6 of first main surface 1 and three point reference plane 94 is the bow.

As shown in FIG. 6, when position 91 of center 6 of first main surface 1 is lower than three point reference plane 94, the bow is a negative value. As shown in FIG. 7, when position 91 of center 6 of first main surface 1 is higher than three point reference plane 94, the bow is a positive value. In the present specification, it is assumed that first main surface 1 is concave when the bow has a negative value (see FIG. 6). On the other hand, it is assumed that first main surface 1 is convex when the bow is a positive value (see FIG. 7).

In silicon carbide epitaxial substrate 100 according to the present embodiment, the bow of first main surface 1 is, for example, a negative value. The bow of first main surface 1 may be, for example, −20 m or less, or −40 m or less. The lower limit of the bow of first main surface 1 is not particularly limited, but may be, for example, −80 m or more.

In silicon carbide epitaxial substrate 100 according to the present embodiment, the warp of first main surface 1 is, for example, 60 m or less. The warp of first main surface 1 may be, for example, 50 m or less, or 40 m or less. The lower limit of warp of first main surface 1 is not particularly limited. The lower limit may be, for example, 10 m or more.

(Method of Manufacturing Silicon Carbide Epitaxial Substrate)

Next, a method of manufacturing silicon carbide epitaxial substrate 100 according to the present embodiment will be described.

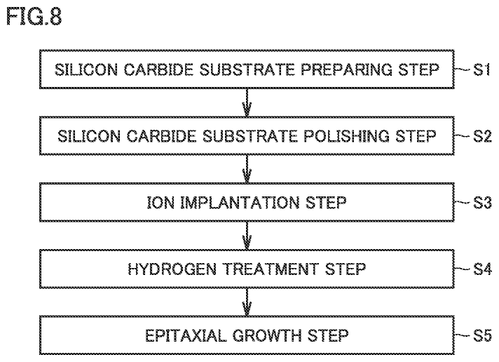

FIG. 8 is a flowchart showing an outline of a method of manufacturing a silicon carbide epitaxial substrate according to the present embodiment. As shown in FIG. 8, the method of manufacturing silicon carbide epitaxial substrate 100 according to the present embodiment mainly includes a silicon carbide substrate preparing step (S1), a silicon carbide substrate polishing step (S2), an ion implantation step (S3), a hydrogen treatment step (S4), and an epitaxial growth step (S5).

A silicon carbide substrate preparing step (S1) is performed. For example, a silicon carbide single crystal having a polytype of 4H is produced by a sublimation method. Next, silicon carbide substrate 10 is prepared by slicing the silicon carbide single crystal using, for example, a wire saw. Silicon carbide substrate 10 contains an n-type impurity such as nitrogen. The conductivity type of silicon carbide substrate 10 is, for example, n-type.

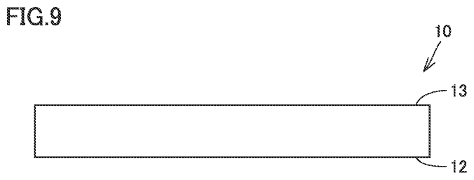

As shown in FIG. 9, silicon carbide substrate 10 has third main surface 13 and second main surface 12 opposite to third main surface 13. Third main surface 13 is, for example, a surface inclined in the off direction by an off angle with respect to the {0001} plane. The off angle is, for example, from 2° to 6°. The off direction is, for example, the <11-20> direction. The maximum diameter of third main surface 13 of silicon carbide substrate 10 is, for example, 150 mm.

Next, a silicon carbide substrate polishing step (S2) is performed. Specifically, a mechanical polishing step is performed at first. In the mechanical polishing step, mechanical polishing is performed on third main surface 13 of silicon carbide substrate 10. Specifically, silicon carbide substrate 10 is held by the polishing head so that third main surface 13 faces the surface plate. A slurry containing abrasive grains is supplied between the surface plate and third main surface 13. The abrasive grains are, for example, diamond abrasive grains. Second main surface 12 is also mechanically polished in the same manner as third main surface 13.

Next, a chemical mechanical polishing step is performed. In the chemical mechanical polishing step, chemical mechanical polishing is performed on third main surface 13 of silicon carbide substrate 10. Specifically, silicon carbide substrate 10 is held by the polishing head so that third main surface 13 of silicon carbide substrate 10 faces the polishing cloth provided on the surface plate. The polishing cloth is Supreme manufactured by Nitta Haas Inc., for example. An abrasive is supplied between the polishing cloth and third main surface 13. The abrasive is, for example, DSC-0902 manufactured by Fujimi Inc. The machining pressure (surface pressure) is, for example, 400 g/cm². The rotation speed of the surface plate is, for example, 60 rpm. The rotation speed of the polishing head is, for example, 60 rpm. Second main surface 12 is also subjected to chemical mechanical polishing in the same manner as third main surface 13. By performing polishing on third main surface 13, a basal plane dislocation (not shown) formed by polishing damage occurs in third main surface 13.

Next, an ion implantation step (S3) is performed. Specifically, two stage ion implantation is performed on the entire surface of third main surface 13. For the ion implantation, for example, a parallel ion implantation apparatus (IMPHEAT) manufactured by Nisshin Ion Instruments Co., Ltd. is used. The ion species is, for example, aluminum ions (Al⁺). The temperature of silicon carbide substrate 10 is, for example, room temperature. In the first ion implantation step, for example, the energy is 530 keV and the dose amount is 2.8×10¹⁴ cm⁻². In the second ion implantation step, for example, the energy is 280 keV and the dose amount is 2.0×10¹⁴ cm⁻².

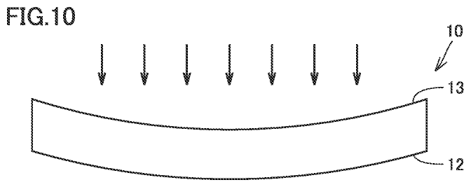

As shown in FIG. 10, ion implantation is performed on third main surface 13 using the conditions described above. The direction of the arrow shown in FIG. 10 is the ion implantation direction. As a result, silicon carbide substrate 10 is concavely curved. Specifically, when silicon carbide substrate 10 is disposed on a flat surface such that second main surface 12 of silicon carbide substrate 10 is in contact with the flat surface, silicon carbide substrate 10 is curved such that the vicinity of the center of second main surface 12 is in contact with the flat surface and the outer edge of second main surface 12 is spaced from the flat surface. Third main surface 13 is curved substantially along the shape of second main surface 12. That is, the bow of third main surface 13 is a negative value.

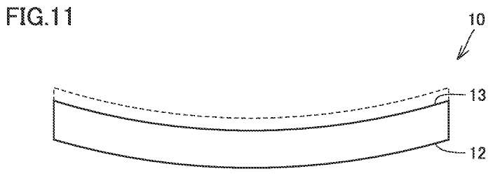

Next, a hydrogen treatment step (S4) is performed. In the hydrogen treatment step (S4), hydrogen treatment is performed on third main surface 13 while silicon carbide substrate 10 is heated. Specifically, silicon carbide substrate 10 is placed in a chamber. Next, the temperature of silicon carbide substrate 10 is raised to about 1630° C. Hydrogen gas is then introduced into the chamber. The flow rate of the hydrogen-containing gas is adjusted to be 100 slm, for example. As a result, silicon carbide substrate 10 is etched on third main surface 13 (see FIG. 11). As a result, a part of the basal plane dislocation formed on third main surface 13 is removed. Although the bow of third main surface 13 may change due to partial relaxation of the strain of silicon carbide substrate 10 by the above etching, the bow of third main surface 13 has a negative value even after the hydrogen treatment step in silicon carbide substrate 10.

Next, an epitaxial growth step (S5) is performed. In the epitaxial growth step (S5), the temperature of the chamber is first raised to, for example, about 1630° C. A gas mixture comprising, for example, silane, propane, ammonia and hydrogen is then introduced into the chamber. To be more specific, the flow rate of the silane gas is adjusted to be, for example, 115 sccm. The flow rate of propane gas is adjusted to be 57.6 sccm, for example. The flow rate of the ammonia gas is adjusted to be, for example, 2.5×10⁻² sccm. The flow rate of the hydrogen-containing gas is adjusted to provide 100 slm. By introducing a mixed gas into the chamber, silicon carbide epitaxial layer 20 is formed on third main surface 13 of silicon carbide substrate 10 by epitaxial growth.

In the epitaxial growth step (S5), silicon carbide substrate 10 reaches a high temperature of about 1600° C. When silicon carbide substrate 10 is convexly curved under high temperature, stress is concentrated from the outer circumference of third main surface 13 toward the center. From another viewpoint, the stress is high in the vicinity of the center of third main surface 13, and the stress is low in the vicinity of the outer circumference of third main surface 13. On the other hand, as shown in FIG. 10, when silicon carbide substrate 10 is concavely curved at a high temperature, the stress is released from the center of third main surface 13 toward the outer circumference. From another viewpoint, the stress is low in the vicinity of the center of third main surface 13, and the stress is high in the vicinity of the outer circumference of third main surface 13. In a region where stress is high, double Shockley stacking fault 7 is likely to occur in silicon carbide epitaxial layer 20.

In the method of manufacturing silicon carbide epitaxial substrate 100 according to the present embodiment, epitaxial growth is performed in a state where the bow of third main surface 13 of silicon carbide substrate 10 has a negative value. To be specific, in silicon carbide substrate 10 after the ion implantation step (S3) and before the hydrogen treatment step (S4), epitaxial growth is performed in a state where the bow of third main surface 13 is, for example, −20 m or less. The bow of third main surface 13 may be, for example, −40 m or less, or −60 m or less. As a result, the stress is low in the vicinity of the center of third main surface 13, and the stress is high in the vicinity of the outer circumference of third main surface 13. As a result, a large number of double Shockley stacking faults 7 occur near the outer circumference where the stress is high. As described above, silicon carbide epitaxial substrate 100 according to the present embodiment is manufactured (see FIG. 2).

(Method of Manufacturing Silicon Carbide Semiconductor Device)

Next, a method of manufacturing a silicon carbide semiconductor device 300 according to the present embodiment will be described.

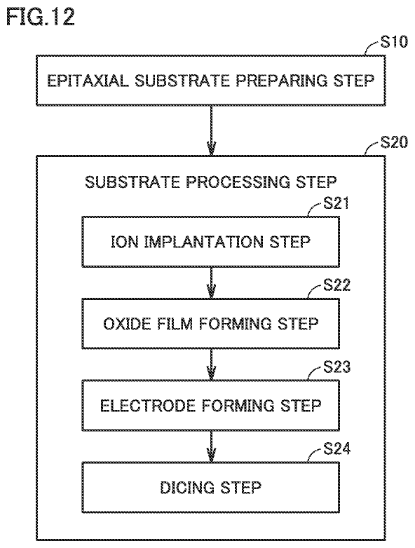

FIG. 12 is a flowchart showing an outline of a method of manufacturing a silicon carbide semiconductor device according to the present embodiment. As shown in FIG. 12, the method of manufacturing a silicon carbide semiconductor device according to the present embodiment mainly includes an epitaxial substrate preparing step (S10: FIG. 12) and a substrate processing step (S20: FIG. 12).

First, an epitaxial substrate preparing step (S10: FIG. 12) is performed. Specifically, silicon carbide epitaxial substrate 100 is prepared by the above-described method of manufacturing silicon carbide epitaxial substrate 100 (see FIG. 2).

Next, a substrate processing step (S20: FIG. 12) is performed. Specifically, silicon carbide epitaxial substrate 100 is processed to manufacture a silicon carbide semiconductor device. “Processing” includes various types of processing such as ion implantation, heat treatment, etching, oxide film formation, electrode formation, and dicing. That is, the substrate processing step may include at least one of ion implantation, heat treatment, etching, oxide film formation, electrode formation, and dicing.

Hereinafter, a method of manufacturing a metal oxide semiconductor field effect transistor (MOSFET) as an example of a silicon carbide semiconductor device will be described. The substrate processing step (S20: FIG. 12) includes, for example, an ion implantation step (S21: FIG. 12), an oxide film forming step (S22: FIG. 12), an electrode forming step (S23: FIG. 12), and a dicing step (S24: FIG. 12).

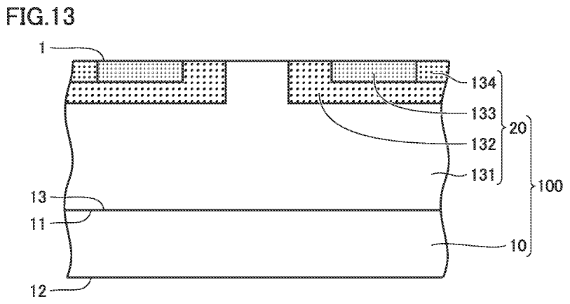

First, an ion implantation step (S21: FIG. 12) is performed. A p-type impurity such as aluminum (Al) is implanted into first main surface 1 on which a mask (not shown) having an opening is formed. Accordingly, a body region 132 having a p-type conductivity type is formed. Next, an n-type impurity such as phosphorus (P) is implanted into a predetermined position in body region 132. Accordingly, a source region 133 having an n-type conductivity type is formed. Next, a p-type impurity such as aluminum is implanted into a predetermined position in source region 133. Thus, a contact region 134 having a p-type conductivity type is formed (see FIG. 13).

In silicon carbide epitaxial layer 20, a portion other than body region 132, source region 133, and contact region 134 becomes a drift region 131. Source region 133 is separated from drift region 131 by body region 132. The ion implantation may be performed by heating silicon carbide epitaxial substrate 100 to about 300° C. to about 600° C. After the ion implantation, activation annealing is performed on silicon carbide epitaxial substrate 100. By the activation annealing, impurities implanted into silicon carbide epitaxial layer 20 are activated, and carriers are generated in each region. The atmosphere of activation annealing is, for example, an argon (Ar) atmosphere. The temperature of activation annealing is, for example, about 1800° C. The activation annealing time is, for example, about 30 minutes.

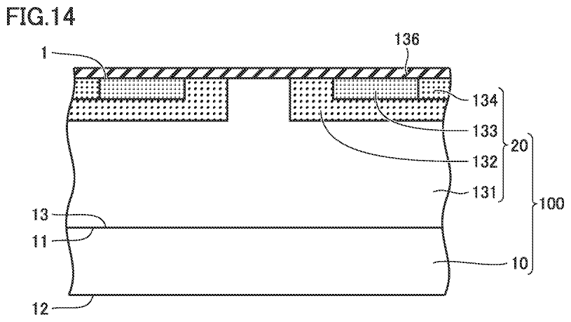

Next, an oxide film forming step (S22: FIG. 12) is performed. For example, when silicon carbide epitaxial substrate 100 is heated in an atmosphere containing oxygen, an oxide film 136 is formed on first main surface 1 (see FIG. 14). Oxide film 136 is made of, for example, silicon dioxide. Oxide film 136 functions as a gate insulating film. The temperature of the thermal oxidation treatment is, for example, about 1300° C. The thermal oxidation treatment is performed for about 30 minutes, for example.

After oxide film 136 is formed, heat treatment may be further performed in a nitrogen atmosphere. For example, heat treatment is performed in a nitrogen monoxide atmosphere at about 1100° C. for about 1 hour. Thereafter, heat treatment is carried out in an argon atmosphere. For example, heat treatment is performed in an argon atmosphere at about 1100° C. to 1500° C. for about one hour.

Next, an electrode forming step (S23: FIG. 12) is performed. Specifically, a gate electrode 141 may be formed on oxide film 136. Gate electrode 141 is formed by, for example, a chemical vapor deposition (CVD) method. Gate electrode 141 is made of, for example, polysilicon having conductivity. Gate electrode 141 is formed at a position facing source region 133 and body region 132.

Next, an interlayer insulating film 137 covering gate electrode 141 is formed. Interlayer insulating film 137 is formed by, for example, a CVD method. Interlayer insulating film 137 is made of, for example, silicon dioxide. Interlayer insulating film 137 is formed to be in contact with gate electrode 141 and oxide film 136. Next, portions of oxide film 136 and interlayer insulating film 137 are removed by etching. Accordingly, source region 133 and contact region 134 are exposed from oxide film 136.

Next, a source electrode 142 is formed in the exposed portion by sputtering, for example. Source electrode 142 is made of, for example, titanium, aluminum, silicon, or the like. After source electrode 142 is formed, source electrode 142 and silicon carbide epitaxial substrate 100 are heated at a temperature of, for example, about 900° C. to 1100° C. Accordingly, source electrode 142 and silicon carbide epitaxial substrate 100 are in ohmic contact with each other. Next, a wiring layer 138 is formed in contact with source electrode 142. Wiring layer 138 is made of a material containing aluminum, for example. Next, a drain electrode 143 is formed on second main surface 12. Drain electrode 143 is made of, for example, an alloy containing nickel and silicon (for example, NiSi).

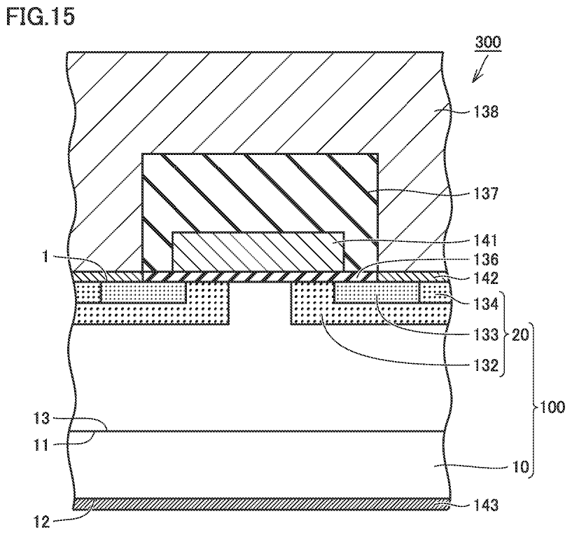

Next, a dicing step (S24: FIG. 12) is performed. For example, by dicing silicon carbide epitaxial substrate 100 along dicing lines, silicon carbide epitaxial substrate 100 is divided into a plurality of semiconductor chips. As described above, silicon carbide semiconductor device 300 is manufactured (see FIG. 15).

Although the method of manufacturing a silicon carbide semiconductor device according to the present disclosure has been described above by exemplifying a planar MOSFET, the manufacturing method according to the present disclosure is not limited thereto. The manufacturing method according to the present disclosure can be applied to a silicon carbide semiconductor device such as a trench type MOSFET, an Insulated Gate Bipolar Transistor (IGBT), a Schottky Barrier Diode (SBD), a thyristor, a Gate Turn Off thyristor (GTO), or a PN diode.

Next, operations and effects of the method of manufacturing silicon carbide epitaxial substrate 100 and silicon carbide semiconductor device 300 according to the present embodiment will be described.

For example, in silicon carbide of a polytype of 4H, the basal plane perfect dislocation is decomposed into two basal plane partial dislocations. A stacking fault existing between two basal plane portions dislocation is called a Shockley stacking fault. The Shockley stacking fault is classified into four types of stacking faults according to differences in the stacking structure. Specifically, the Shockley stacking fault is classified into a single Shockley stacking fault, a double Shockley stacking fault, a triple Shockley stacking fault, and a quadruple Shockley stacking fault. Each of the four types of stacking faults has a different emission wavelength. Therefore, it is possible to identify these stacking faults by using the photoluminescence method.

When the area density of single Shockley stacking fault 8 is high, current leakage of the silicon carbide semiconductor device is likely to occur, and reliability is significantly degraded. On the other hand, it is desirable to reduce double Shockley stacking fault 7 in consideration of the long-term reliability of the silicon carbide semiconductor device, but the influence on the reliability degradation is not so large as compared with single Shockley stacking fault 8. Therefore, even if double Shockley stacking fault 7 remains in silicon carbide epitaxial substrate 100 to some extent, the influence on the reliability degradation is not so significant.

As a result of intensive studies, the inventors have conceived that single Shockley stacking fault 8 is reduced by actively increasing double Shockley stacking fault 7. When silicon carbide substrate 10 is convexly curved under high temperature, stress is concentrated from the outer circumference of the main surface (upper surface) toward the center. From another point of view, the stress is high in the vicinity of the center of the main surface, and the stress is low in the vicinity of the outer circumference of the main surface. On the other hand, as shown in FIG. 10, when silicon carbide substrate 10 is concavely curved at a high temperature, the stress is released from the center of the main surface toward the outer circumference. From another point of view, the stress is low near the center of the main surface, and the stress is high near the outer circumference of the main surface. In a region where stress is high, double Shockley stacking fault 7 is likely to occur in silicon carbide epitaxial layer 20. If the region of the normal polytype of 4H is converted into double Shockley stacking fault 7, the region is not converted into single Shockley stacking fault 8.

Specifically, by forming silicon carbide epitaxial layer 20 on silicon carbide substrate 10 in a state in which silicon carbide substrate 10 is curved in a concave shape to some extent under high temperature, the stress in outer circumferential region 31 of main surface 1 of silicon carbide epitaxial layer 20 is made higher than the stress in central region 32 of main surface 1. Thus, double Shockley stacking fault 7 is positively formed in outer circumferential region 31. To be more specific, when the area density of double Shockley stacking fault 7 in outer circumferential region 31 is defined as first area density and the area density of double Shockley stacking fault 7 in central region 32 is defined as second area density, the first area density is set to be five times or more than the second area density. Accordingly, it is possible to reduce the probability that single Shockley stacking fault 8 is formed in outer circumferential region 31. Specifically, the area density of single Shockley stacking fault 8 in outer circumferential region 31 is 0.5 cm⁻² or less.

According to silicon carbide epitaxial substrate 100 of the present embodiment, the area density (second area density) of double Shockley stacking fault 7 in central region 32 is 0.2 cm⁻² or more. By actively increasing double Shockley stacking fault 7 also in central region 32, it is possible to reduce the probability that single Shockley stacking fault 8 is formed in central region 32.

### Example 1

(Sample Preparation)

Next, an example will be described. According to the method of manufacturing silicon carbide epitaxial substrate 100 described above, two silicon carbide substrates 10 having different bow values of third main surface 13 were prepared. The value of bow of third main surface 13 of the sample 1 was −63.1 m. The bow value of third main surface 13 of Sample 2 was +15.9 m. The value of bow is a value after the ion implantation step (S3) and before the hydrogen treatment step (S4). Next, a hydrogen treatment step (S4) was performed on third main surface 13 of silicon carbide substrate 10. Next, silicon carbide epitaxial layer 20 was formed on third main surface 13 by epitaxial growth. Third main surface 13 was a Si (silicon) surface. That is, silicon carbide epitaxial layer 20 was grown on the Si surface. As described above, silicon carbide epitaxial substrate 100 according to each of sample 1 and sample 2 was manufactured.

### EXPERIMENTAL METHOD

Next, the area density (first area density) of double Shockley stacking fault 7 in outer circumferential region 31 of first main surface 1 of silicon carbide epitaxial substrate 100 was measured. Similarly, the area density (second area density) of double Shockley stacking fault 7 in central region 32 was measured. Similarly, the area density (third area density) of single Shockley stacking fault 8 in outer circumferential region 31 was measured. The method of measuring the stacking fault is as described above.

### EXPERIMENTAL RESULTS

TABLE 1

| | Bow of Third | | | | |
|---|---|---|---|---|---|
| | Main Surface | | | First Area | |
| | before Epitaxial | First Area | Second Area | Density/Second | Third Area |
| Sample No. | Growth (μm) | Density (cm⁻²) | Density (cm⁻²) | Area Density | Density (cm⁻²) |
| Sample 1 | −63.1 | 2.2 | 0.3 | 7.3 | 0.3 |
| Sample 2 | +15.9 | 0.6 | 3.2 | 0.2 | 2.8 |

Table 1 shows results of first area density, second area density, first area density/second area density, and third area density in silicon carbide epitaxial substrate 100 according to each of Sample 1 and Sample 2. As shown in Table 1, it was confirmed that the area density (third area density) of the single Shockley stacking fault could be significantly reduced in silicon carbide epitaxial substrate 100 according to Sample 1 compared to silicon carbide epitaxial substrate 100 according to Sample 2. The numerical values of the experiment are first area density 2.2 cm⁻², second area density 0.3 cm⁻², first area density/second area density 7.3, and third area density 0.3 cm⁻². However, the effects of the invention can also be achieved by numerical values of first area density 1.0 cm⁻², second area density 0.2 cm⁻², first area density/second area density 5.0, and third area density 0.5 cm⁻²

### Example 2

Next, a change in bow before and after epitaxial growth will be described. First, a plurality of silicon carbide substrates 10 having different bow values of third main surface 13 were prepared. The value of bow is a value after the ion implantation step (S3) and before the hydrogen treatment step (S4). Next, a hydrogen treatment step (S4) was performed on third main surface 13 of silicon carbide substrate 10. Next, silicon carbide epitaxial layer 20 was formed on third main surface 13 of silicon carbide substrate 10 by epitaxial growth. The thickness of silicon carbide epitaxial layer 20 was 10 m. Next, the bow of first main surface 1 of silicon carbide epitaxial layer 20 was measured.

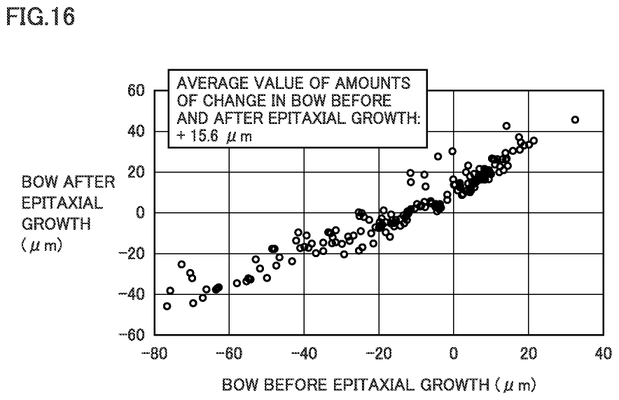

FIG. 16 is a diagram showing changes in bow before and after epitaxial growth. The horizontal axis of FIG. 16 is the bow of third main surface 13 of silicon carbide substrate 10 before epitaxial growth (before hydrogen treatment). The vertical axis of FIG. 16 is the bow of first main surface 1 of silicon carbide epitaxial layer 20 after epitaxial growth. The bow of third main surface 13 before epitaxial growth is in a range of more than −80 m and less than 40 m, for example. The bow of first main surface 1 after epitaxial growth is in a range of more than −50 m and less than 50 m, for example. As shown in FIG. 16, it was confirmed that the bow of first main surface 1 after epitaxial growth was larger by 15.6 m than the bow of third main surface 13 before epitaxial growth.

The embodiments and examples disclosed herein are to be considered in all respects as illustrative and not restrictive. The scope of the present invention is defined not by the above-described embodiments and examples but by the claims, and is intended to include meanings equivalent to the claims and all modifications within the scope.

### DESCRIPTION OF SYMBOLS

1 main surface (first main surface), 3 orientation flat, 4 arc-shaped portion, 5 outer circumferential edge, 6 center, 7 double Shockley stacking fault, 8 single Shockley stacking fault, 10 silicon carbide substrate, 11 boundary surface, 12 second main surface, 13 third main surface, 20 silicon carbide epitaxial layer, 31 outer circumferential region, 32 central region, 91 position, 92 highest position, 93 lowest position, 94 point reference plane, 95 fifth position, 96 sixth position, 97 seventh position, 100 silicon carbide epitaxial substrate, 101 first direction, 102 second direction, 131 drift region, 132 body region, 133 source region, 134 contact region, 136 oxide film, 137 interlayer insulating film, 138 wiring layer, 141 gate electrode, 142 source electrode, 143 drain electrode, 154 first distance, 155 second distance, 300 silicon carbide semiconductor device, W maximum diameter

1. A silicon carbide epitaxial substrate comprising:
a silicon carbide substrate; and
a silicon carbide epitaxial layer disposed on the silicon carbide substrate,
wherein the silicon carbide epitaxial layer includes a boundary surface in contact with the silicon carbide substrate and a main surface opposite to the boundary surface,
the main surface has an outer circumferential edge, an outer circumferential region extending within 5 mm from the outer circumferential edge, and a central region surrounded by the outer circumferential region,
when an area density of double Shockley stacking faults in the outer circumferential region is defined as a first area density, and an area density of double Shockley stacking faults in the central region is defined as a second area density, the first area density is five or more times as large as the second area density,
the second area density is 0.2 cm⁻² or more, and
an area density of single Shockley stacking faults in the outer circumferential region is 0.5 cm⁻² or less.

2. The silicon carbide epitaxial substrate according to claim 1, wherein a bow quantitatively defining an amount of warpage of the main surface is a negative value.

3. The silicon carbide epitaxial substrate according to claim 1, wherein the second area density is 1.0 cm⁻² or less.

4. The silicon carbide epitaxial substrate according to claim 1, wherein the first area density is 2.0 cm⁻² or more.

5. A method of manufacturing a silicon carbide semiconductor device, the method comprising:
preparing the silicon carbide epitaxial substrate according to claim 1; and
processing the silicon carbide epitaxial substrate.

6. The silicon carbide epitaxial substrate according to claim 1, wherein a bow quantitatively defining an amount of warpage of the main surface is a negative value, wherein the second area density is 1.0 cm⁻² or less.

7. The silicon carbide epitaxial substrate according to claim 1, wherein a bow quantitatively defining an amount of warpage of the main surface is a negative value, wherein the first area density is 2.0 cm⁻² or more.

8. The silicon carbide epitaxial substrate according to claim 1, wherein the second area density is 1.0 cm⁻² or less, wherein the first area density is 2.0 cm⁻² or more.

9. The silicon carbide epitaxial substrate according to claim 1, wherein a bow quantitatively defining an amount of warpage of the main surface is a negative value,
wherein the second area density is 1.0 cm⁻² or less, wherein the first area density is 2.0 cm⁻² or more.

10. A method of manufacturing a silicon carbide semiconductor device, the method comprising:
preparing the silicon carbide epitaxial substrate according to claim 9; and
processing the silicon carbide epitaxial substrate.
